(19) United States
(12) Patent Application Publication
(10) Pub. No.: US 2010/0295570 A1
(43) Pub. Date: Nov. 25, 2010

(54) Probe Connector

(76) Inventors: Te-Hung Yin, Taipei (TW); Jui-Pin Lin, Taipei (TW); Yung-Yi Chen, Taipei (TW); Shu-Fang Li, Taipei (TW)

Correspondence Address: LIN & ASSOCIATES INTELLECTUAL PROPERTY, INC., P.O. BOX 2339, SARATOGA, CA, 95070-0339, US

(21) Appl. No.: 12/647,415

(22) Filed: Dec. 25, 2009

(30) Foreign Application Priority Data
May 22, 2009 (CN) 200920057315.4

(51) Int. Cl. G01R 31/02

(52) U.S. Cl. 324/757

(57) ABSTRACT

A probe connector for being sucked by a suction nozzle and then soldered to a PCB by moving the suction nozzle has a barrel. One end of the barrel has a base, the other end of the barrel is formed with an opening. A periphery of the barrel has a portion protruded outwards to form a ring-shaped flange. The flange has a ring-shaped flat surface back to the base for engaging with a bottom of the suction nozzle. A probing pin includes a base portion received in the barrel and a contact portion projecting outside the barrel through the opening. An elastic element received in the barrel is disposed between the base and the base portion of the probing pin.

### BACKGROUND OF THE INVENTION

1. Field of the Invention

The present invention relates to an electrical connector, and more particularly to a probe connector.

2. The Related Art

A conventional probe connector includes a barrel, a probing pin and an elastic element. One end of the barrel has a base and the other end of the barrel forms an opening. One end of the probing pin is disposed inside of the barrel and the other end projects outside the barrel from the opening. The elastic element is received in the barrel and disposed between the base and the probing pin. In progress of soldering the probe connector to a PCB, a clutch jig clutches one end of the probe connector where the probing pin is disposed, and then a suction nozzle sucks the clutch jig to take the probe connector to solder to the PCB. Nevertheless, the soldering process will adds the manufacture cost of the clutch jig, furthermore, the operation needs much more time and manpower, which influences the soldering efficiency. So it is desirable and necessary to design a probe connector which can solve or at least overcome the problems mentioned above.

### SUMMARY OF THE INVENTION

Accordingly, an object of the present invention is to provide a probe connector for being sucked by a suction nozzle and then soldered to a PCB by moving the suction nozzle. The probe connector has a barrel. One end of the barrel has a base and the other end of the barrel is formed with an opening. A periphery of the barrel has a portion protruded outwards to form a ring-shaped flange. The flange has a ring-shaped flat surface back to the base for engaging with a bottom of the suction nozzle. A probing pin includes a base portion received in the barrel and a contact portion projecting outside the barrel through the opening. An elastic element received in the barrel is disposed between the base and the base portion of the probing pin.

As described above, the suction nozzle can directly sucks the flat surface of the flange protruded outwards from the periphery of the barrel to clutch the probe connector to solder to the PCB, without using other jig devices, which not only simplifies the operation of the soldering but also saves the time and labor, reducing production cost and increasing soldering efficiency.

### BRIEF DESCRIPTION OF THE DRAWINGS

The present invention will be apparent to those skilled in the art by reading the following description of an embodiment thereof, with reference to the attached drawings, in which:

FIG. 1 is an assembled, perspective view of a probe connector of an embodiment in accordance with the present invention; and

FIG. 2 is a cross-sectional view that the probe connector shown in FIG. 1 is absorbed by a suction nozzle.

### DETAILED DESCRIPTION OF THE EMBODIMENT

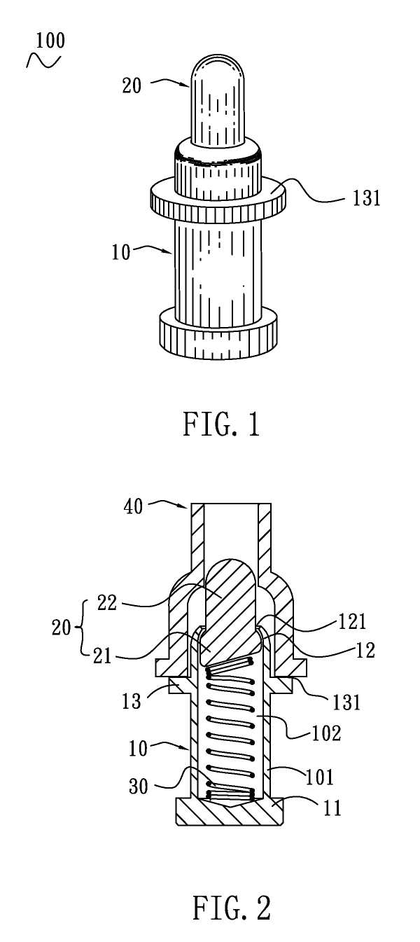

Please refer to FIG. 1 and FIG. 2, a probe connector 100 according to the present invention is shown. The probe connector 100 includes a barrel 10, a telescopic probing pin 20 and an elastic element 30. The barrel 10 and the probing pin 20 are made of metallic materials.

Please refer to FIG. 2, the barrel 10 defines an enclosure 101 to surround a chamber 102 therein. One end of the enclosure 101 is sealed by a base 11, the other end of the enclosure 101 extends inwards to form a ring-shaped shoulder 12. The shoulder 12 surrounds an opening 121. A periphery of the barrel 10 has a portion protruded outwards to form a ring-shaped flange 13. The flange 13 has a circular flat surface 131 back to the base 11 for engaging with a bottom of a suction nozzle 40. The probing pin 20 has a base portion 21 and a contact portion 22 extending from an end of the base portion 21. The base portion 21 is received in the chamber 102 of the barrel 10 and the contact portion 22 extends out of the barrel 10 through the opening 121. The outer dimension of the base portion 21 is less than the inner dimension of the barrel 10 for allowing the base portion 21 movably received within the chamber 102. The dimension of the opening 121 is less than the outer dimension of the base portion 21 for preventing the base portion 21 being removed from the chamber 102. The elastic element 30 is received in the chamber 102 of the barrel 10. Two opposite ends of the elastic element 30 respectively resist on the base 11 and a bottom side of the base portion 21 of the probing pin 20.

Please refer to FIG. 2 again, when the probe connector 100 is soldered to a PCB (not shown), the suction nozzle 40 sucks the flat surface 131 of the flange 13 firmly, and then the probe connector 100 is taken to solder to the PCB by moving the suction nozzle 40.

As describe above, the suction nozzle 40 can directly suck the flat surface 131 of the flange 13 to move the probe connector 100 to solder to the PCB, without using other jig devices, which not only simplifies the operation of the soldering but also saves the time and labor, reducing production cost and increasing soldering efficiency.

Furthermore, the present invention is not limited to the embodiment described above; various additions, alterations and the like may be made within the scope of the present invention by a person skilled in the art. For example, respective embodiments may be appropriately combined.

What is claimed is:

1. A probe connector for being sucked by a suction nozzle and then soldered to a PCB by moving the suction nozzle, comprising:
a barrel, one end of the barrel having a base, the other end of the barrel formed with an opening, a periphery of the barrel having a portion protruded outwards to form a ring-shaped flange, the flange having a ring-shaped flat surface back to the base for engaging with a bottom of the suction nozzle;
a probing pin, the probing pin having a base portion received in the barrel and a contact portion projecting outside the barrel through the opening; and
an elastic element received in the barrel and disposed between the base and the base portion of the probing pin.
